(19) United States
(12) Patent Application Publication
(10) Pub. No.: US 2013/0161543 A1
(43) Pub. Date: Jun. 27, 2013

(54) ZONEPLATE AND MASK PATTERN MEASURING DEVICE COMPRISING THE ZONEPLATE

(71) Applicants: Jong-Ju PARK, Hwaseong-si (KR); Dong-Gun LEE, Hwaseong-si (KR); Seong-Sue KIM, Hwaseong-si (KR); Chang-Hoon CHOI, Hwaseong-si (KR)

(72) Inventors: Jong-Ju PARK, Hwaseong-si (KR); Dong-Gun LEE, Hwaseong-si (KR); Seong-Sue KIM, Hwaseong-si (KR); Chang-Hoon CHOI, Hwaseong-si (KR)

(21) Appl. No.: 13/585,978

(22) Filed: Aug. 15, 2012

(30) Foreign Application Priority Data
Dec. 23, 2011 (KR) 10-2011-0141268

(51) Int. Cl. H01L 31/0232; G02B 27/44

(52) U.S. Cl. 250/550; 359/565

(57) ABSTRACT

A zoneplate includes a first pattern having a first thickness, the first pattern including a first material, and a second pattern adjacent to the first pattern and having a second thickness larger than the first thickness, the second pattern including a second material, incident light incident on the first pattern from the outside passing through the first pattern, and incident light incident on the second pattern from the outside passing through the second pattern.

### CROSS-REFERENCE TO RELATED APPLICATION

Korean Patent Application No. 10-2011-0141268 filed on Dec. 23, 2011 in the Korean Intellectual Property Office, and entitled “Zoneplate and Mask Pattern Measuring Device Comprising the Zoneplate,” is incorporated by reference herein in its entirety.

### BACKGROUND

1. Field

The present inventive concept relates to a zoneplate and to a mask pattern measuring device including the zoneplate.

2. Description of the Related Art

Recently, along with miniaturization of line widths in semiconductor circuits, a light source with a shorter wavelength is required. Accordingly, studies are being conducted on an exposure process using extreme ultraviolet (EUV) light having a wavelength of 50 nm or less as an exposure light source.

As difficulty of the exposure process gradually increases, a small error of a mask may cause a fatal error to a circuit pattern on a wafer. Thus, when a pattern is implemented on the wafer using a photomask, in order to evaluate in advance effects of various defects of the photomask on the wafer, a mask pattern is measured and these defects are inspected.

### SUMMARY

Example embodiments provide a zoneplate with improved light focusing efficiency.

Example embodiments also provide a method for manufacturing a zoneplate with improved light focusing efficiency.

Example embodiments also provide a mask pattern measuring device including a zoneplate with improved light focusing efficiency, thereby improving measurement efficiency.

According to an aspect of the example embodiments, there is provided a zoneplate a first pattern having a first thickness, the first pattern including a first material, and a second pattern adjacent to the first pattern and having a second thickness larger than the first thickness, the second pattern including a second material, wherein incident light incident on the first pattern from the outside passes through the first pattern, and incident light incident on the second pattern from the outside passes through the second pattern.

The first material and the second material may include a same light transmissive material.

A refractive index of the light transmissive material may be defined by a+bi, where a and b are real numbers and b is smaller than 0.02.

The light transmissive material may include silicon nitride (Si₃N₄).

A refractive index of the light transmissive material may be n, a wavelength of the incident light is λ, and a difference t between the first thickness and the second thickness is presented by t=(2k−1)π*(n−1)/λ, where k is a natural number. For example, k may be 1.

The first and second pattern may be arranged to have constructive interference between non-diffraction light (0th order diffraction light) of first transmission light having passed through the first pattern and 1st order diffraction light of second transmission light having passed through the second pattern.

There may be a phase difference of (2k−1)π(k is a natural number) between the first transmission light immediately after passing through the first pattern and the second transmission light immediately after passing through the second pattern. For example, k may be 1.

The first pattern and the second pattern may be elliptically shaped and are concentric.

According to another aspect of the example embodiments, there is provided a mask pattern measuring device, including a light source configured to irradiate light, a zoneplate configured to transmit the light irradiated from the light source, the zoneplate including a first pattern having a first thickness and a second pattern adjacent to the first pattern and having a second thickness larger than the first thickness, the first and second patterns being arranged such that light having passed through the first pattern and light having passed through the second pattern constructively interfere, a mask having a mask pattern and configured to reflect light transmitted through the zoneplate, and a detector configured to detect the light reflected from the mask.

When an incident angle of incident light incident on the mask is α, a first axis radius of the first pattern may be r1, a first axis radius of the second pattern may be r2, a second axis radius of the first pattern may be r1/(cos α), and a second axis radius of the second pattern may be r2/(cos α).

There may be a phase difference of it between the light having passed through the first pattern and light having passed through the second pattern.

The light source may be configured to emit extreme ultraviolet (EUV) light.

A refractive index of a material included in the first pattern and the second pattern may be a+bi, where a and b are real numbers and b is smaller than 0.02.

According to another aspect of the example embodiments, there is provided a zoneplate, including a first pattern having a first thickness, and a second pattern having a second thickness larger than the first thickness, the second pattern being adjacent the first pattern, wherein light is incident on and transmitted through the first and second patterns from the outside.

The first and second patterns may include a same light transmissive material and are integral with each other.

The first and second pattern may be arranged to have constructive interference between the light passing through the first pattern and the light passing through the second pattern.

The first and second patterns may be arranged alternately and in direct contact with each other.

The first and second patterns may be concentric.

### BRIEF DESCRIPTION OF THE DRAWINGS

Features will become apparent to those of ordinary skill in the art by describing in detail exemplary embodiments with reference to the attached drawings, in which:

FIG. 1 illustrates a perspective view of a zoneplate in accordance with an example embodiment;

FIG. 2 illustrates a cross-sectional view taken along line A-A′ of FIG. 1;

FIG. 3 illustrates an enlarged plan view of part of the zoneplate shown in FIG. 1;

FIG. 4 illustrates a diagram for explaining a shape of the zoneplate in accordance with an example embodiment;

FIG. 5 illustrates a flowchart showing a method of manufacturing a zoneplate in accordance with an example embodiment;

FIGS. 6 to 8 illustrate stages in a method of manufacturing a zoneplate in accordance with an example embodiment;

FIG. 9 illustrates a conceptual block diagram of a mask pattern measuring device in accordance with an example embodiment;

FIG. 10 illustrates a flowchart for explaining a method for forming a pattern in accordance with an example embodiment; and

FIGS. 11 and 12 illustrate stages in a method for forming a pattern in accordance with an exemplary embodiment.

### DETAILED DESCRIPTION

Advantages and features of example embodiments and methods of accomplishing the same may be understood more readily by reference to the following detailed description of preferred embodiments and the accompanying drawings. The example embodiments may, however, be embodied in many different forms and should not be construed as being limited to the embodiments set forth herein. Rather, these embodiments are provided so that this disclosure will be thorough and complete and will fully convey the concept of the invention to those skilled in the art, and the example embodiments will only be defined by the appended claims.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

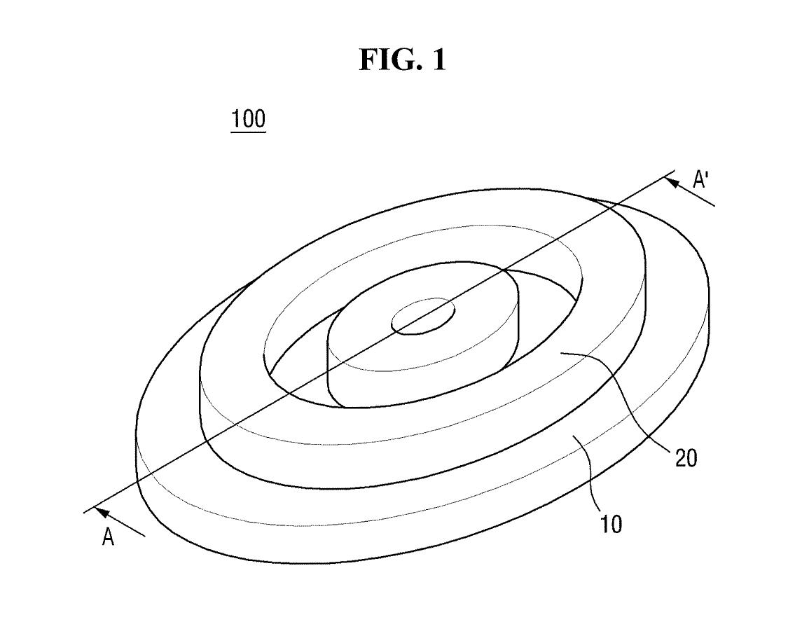

Hereinafter, a zoneplate 100 in accordance with an embodiment will be described with reference to FIGS. 1 to 4.

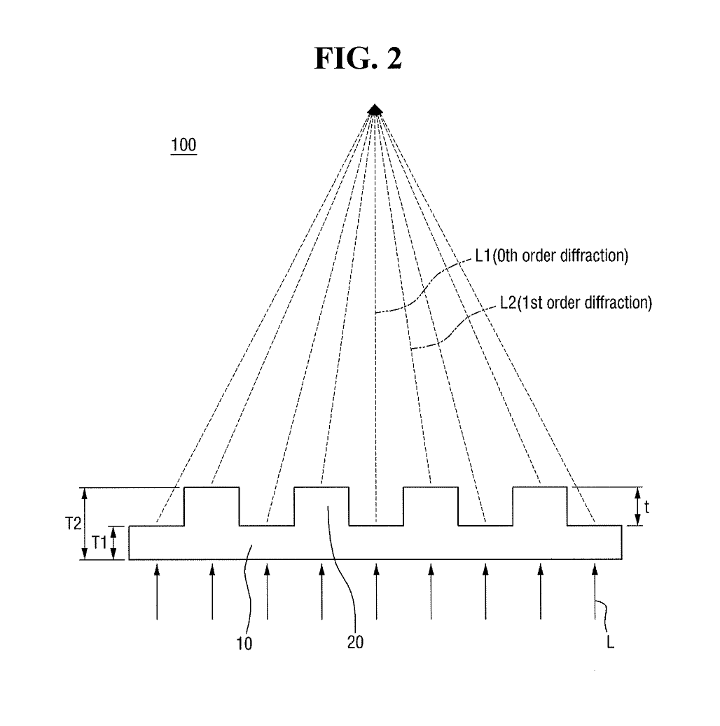

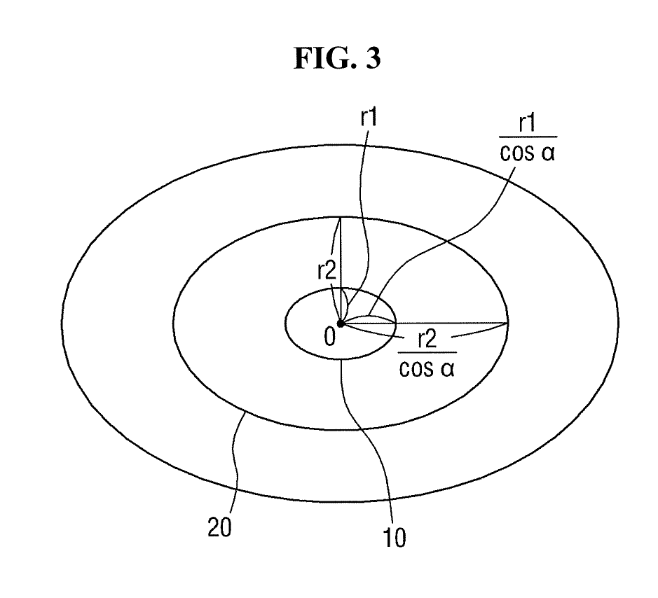

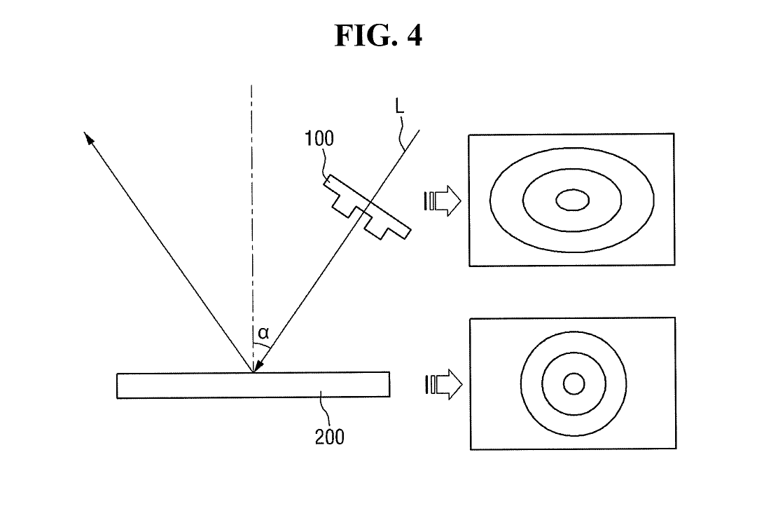

FIG. 1 is a perspective view of a zoneplate in accordance with an embodiment. FIG. 2 is a cross-sectional view taken along line A-A′ of FIG. 1. FIG. 3 is an enlarged plan view of part of the zoneplate shown in FIG. 1. FIG. 4 is a diagram for explaining a shape of the zoneplate in accordance with the embodiment.

First, referring to FIGS. 1 and 2, the zoneplate 100 may include a first pattern 10 having a first thickness T1 and formed of a first material, and a second pattern 20 having a second thickness T2 and formed of a second material. The second pattern 20 may be formed adjacent to the first pattern 10. That is, the zoneplate 100 may be formed by alternately forming the first pattern 10 having the first thickness T1 and the second pattern 20 having the second thickness T2. For example, as illustrated in FIG. 2, bottoms of the first and second patterns 10 and 20 may be arranged to be substantially level, so a bottom of the zoneplate 100 is flat and uniform. Light may be incident on the zoneplate 100 through the bottom.

In FIGS. 1 and 2, for convenience of explanation, only part of the zoneplate 100 is illustrated, i.e., only three pattern portions of the first pattern 10 and two pattern portions of the second pattern 20 are alternately formed with respect to a central point. However, the number of pattern portions of the first pattern 10 and the second pattern 20 is not limited and may be further formed in another region (not shown) similarly to those illustrated in FIGS. 1 and 2.

The first material of the first pattern 10 and the second material of the second pattern 20 may include a same light transmissive material. Accordingly, incident light L incident on the first and second patterns 10 and 20 from the outside may pass through the first pattern 10 and the second pattern 20. For example, as illustrated in FIG. 2, the incident light L incident on the first pattern 10 from the outside may pass through the first pattern 10 to form first transmission light L1, and the incident light L incident on the second pattern 20 from the outside may pass through the second pattern 20 to form second transmission light L2.

Generally, a refractive index of a material can be expressed by the following Equation 1, where a (the phase speed) and b (the extinction coefficient) are real numbers:

Refractive index (n)=a+bi Equation 1

In Equation 1, the value b of the refractive index of the light transmissive material included in both the first pattern 10 and the second pattern 20 may be smaller than 0.02 at wavelengths of interest. That is, the first pattern 10 and the second pattern 20 may include the same light transmissive material having a refractive index of a+bi (a and b are real numbers, b<0.02), thereby transmitting the incident light L incident on the first and second patterns 10 and 20 to form the first transmission light L1 and the second transmission light L2, respectively. In other words, the extinction coefficient of the light transmissive material in the first and second patterns 10 and 20 may be small, such that at predetermined wavelengths, i.e., the wavelengths of interest, light may be transmitted therethrough, i.e., the material may appear transparent at the predetermined wavelengths.

An example of the light transmissive material at wavelengths of interest used to form the first and second patterns 10 and 20 may be silicon nitride (Si₃N₄). The silicon nitride exhibits light transmissivity and also has an advantage of allowing the first pattern 10 and the second pattern 20 to be easily formed to have desired thicknesses, respectively. However, it is merely one example of a light transmissive material that can be included in both the first pattern 10 and the second pattern 20, and if necessary, the light transmissive material may be any material satisfying the conditions of the refractive index.

In the present embodiment, constructive interference occurs between the first transmission light L1 having passed through the first pattern 10 and the second transmission light L2 having passed through the second pattern 20. More specifically, referring to FIG. 2, constructive interference occurs between non-diffraction light (0th order diffraction light) of the first transmission light L1 having passed through the first pattern 10 and 1st order diffraction light of the second transmission light L2 having passed through the second pattern 20. Thus, it may be possible to improve light focusing efficiency of the zoneplate 100, as compared, e.g., to a case where the incident light L cannot pass through the second pattern 20 and fails to form the second transmission light L2, or to a case where destructive interference occurs between the first transmission light L1 and the second transmission light L2.

As described above, in order for constructive interference to occur between the non-diffraction light (0th order diffraction light) of the first transmission light L1 having passed through the first pattern 10 and the 1st order diffraction light of the second transmission light L2 having passed through the second pattern 20, a phase difference between two light paths is required to meet the conditions of constructive interference. That is, the phase difference between the non-diffraction light (0th order diffraction light) of the first transmission light L1 having passed through the first pattern 10 and the 1st order diffraction light of the second transmission light L2 having passed through the second pattern 20 should be 2iπ (i is an integer, i≧0).

In this embodiment, there is a phase difference of (2k−1)π(k is a natural number) between the first transmission light L1 immediately after passing through the first pattern 10 and the second transmission light L2 immediately after passing through the second pattern 20. In other words, there is a phase difference of (2k−1)π(k is a natural number) between the first transmission light L1 formed by transmitting the incident light L through the first pattern 10 having the first thickness T1 and the second transmission light L2 formed by transmitting the incident light L through the second pattern 20 having the second thickness T2 larger than the first thickness T1.

Meanwhile, there is a phase difference of π due to the locations of the patterns between the non-diffraction light (0th order diffraction light) of the first transmission light L1 and the 1st order diffraction light of the second transmission light L2. Thus, since there is a phase difference of 2iπ (i is an integer, i≧0) between the non-diffraction light (0th order diffraction light) of the first transmission light L1 having passed through the first pattern 10 and the 1st order diffraction light of the second transmission light L2 having passed through the second pattern 20, constructive interference occurs therebetween.

A more detailed description thereof will be given below using a simple example. There is a phase difference of it between the incident light L having passed through the first pattern 10 and the incident light L having passed through the second pattern 20. This phase difference may be a phase difference occurring while the incident light L further passes through a thickness t corresponding to a difference between the first thickness T1 and the second thickness T2, i.e., t=T2−T1. Further, there is a phase difference of π due to the pattern formation locations between the non-diffraction light (0th order diffraction light) of the first transmission light L1 having passed through the first pattern 10 and the 1st order diffraction light of the second transmission light L2 having passed through the second pattern 20. Thus, there is a total phase difference of 2π between the non-diffraction light (0th order diffraction light) of the first transmission light L1 formed by transmitting the incident light L through the first pattern 10 and the 1st order diffraction light of the second transmission light L2 formed by transmitting the incident light L through the second pattern 20. Accordingly, constructive interference occurs therebetween.

Meanwhile, the difference t between the first thickness T1 of the first pattern 10 and the second thickness T2 of the second pattern 20 may be designed such that the constructive interference can efficiently occur. When the refractive index of the light transmissive material (e.g., silicon nitride (Si₃N₄)) forming the zoneplate 100 is referred to as n and a wavelength of the incident light L is referred to as λ, t representing a difference between the first thickness T1 and the second thickness T2 may meet the following Equation 2:

t=(2k−1)π*(n−1)/k Equation 2

Here, k is a natural number and its value may be determined according to the phase difference occurring between the first transmission light L1 immediately after passing through the first pattern 10 and the second transmission light L2 immediately after passing through the second pattern 20. In some embodiments, the value k may be set to 1 in order to improve the light focusing efficiency.

Referring again to FIG. 1, the first pattern 10 and the second pattern 20 of the zoneplate 100 may be formed in a concentric elliptical shape. That is, both the first pattern 10 and the second pattern 20 may be formed in an elliptical shape while the centers of the first and second patterns 10 and 20 may be equal to each other, i.e., the centers of the elliptical shapes may coincide to have one common center.

Referring to FIG. 3, when a first axis radius of the first pattern 10 from a common center O is referred to as r1, and a first axis radius of the second pattern 20 from the common center O is referred to as r2, a second axis radius of the first pattern 10 from the common center O may be r1/(cos α), and a second axis radius of the second pattern 20 from the common center O may be r2/(cos λ). For convenience of explanation, FIG. 3 illustrates a plan view of only part of the zoneplate 100 shown in FIG. 1.

Here, a may be an incident angle of the incident light incident on a mask. Specifically, referring to FIG. 4, a may be an incident angle of the incident light L incident on a mask 200 having mask patterns (not shown), i.e., a may be an angle between the light L and a normal to the mask 200, to be measured by using the zoneplate 100 in accordance with the embodiment of the example embodiments. For example, the incident angle α may range from about 4 degrees to about 8 degrees, e.g., the incident angle α may be about 6 degrees.

As described above, forming the first pattern 10 and the second pattern 20 of the zoneplate 100 in accordance with this embodiment in an elliptical shape prevents or substantially minimizes shape distortion when light passes through the zoneplate 100 to be projected onto the mask 200. Referring to FIG. 4, if the incident light L incident on the mask 200 has a predetermined incident angle α, when the light having passed through the zoneplate 100 is projected onto the mask 200, shape distortion occurs due to the incident angle α. Therefore, the elliptical shape of the first and second patterns 10 and 20 accounts for the shape distortion, so light projected onto the mask 200 defines a desired shape thereon.

For example, if a zoneplate is designed to have a concentric circular shape, as opposed to a concentric elliptical shape as in FIG. 4, the shape projected onto a mask may be distorted to be different from a concentric circular shape due to the incident angle α. However, in the present embodiment, by forming the patterns 10 and 20 in a concentric elliptical shape to have the first axis radius and second axis radius in consideration of the distortion, as described above with reference to FIG. 3, it may be possible to adjust the resultant shape of the light projected onto the mask 200 into a desired shape. That is, the zoneplate 100 in accordance with this embodiment is designed to have a concentric elliptical shape (top concentric ellipses in FIG. 4), but the resultant shape projected onto the mask 200 may have a concentric circular shape due to the incidence angle (bottom concentric circles in FIG. 4).

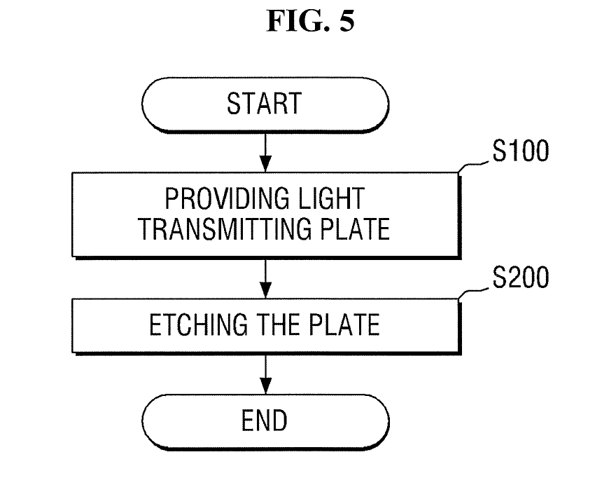

Next, a method of manufacturing a zoneplate in accordance with an embodiment will be described with reference to FIGS. 5 to 8.

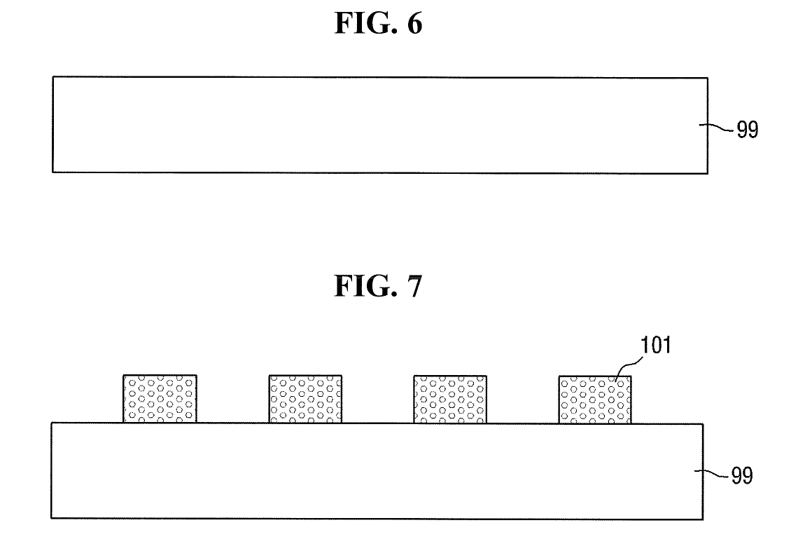

FIG. 5 is a flowchart showing a method of manufacturing a zoneplate in accordance with an embodiment, and FIGS. 6 to 8 illustrate intermediate steps in the method of manufacturing a zoneplate in accordance with the embodiment.

Referring to FIGS. 5 and 6, a light transmissive plate 99 including a light transmissive material is provided (operation S100). The light transmissive material may be, e.g., silicon nitride (Si₃N₄).

Subsequently, referring to FIG. 7, a specific mask film (not shown) may be formed on the light transmissive plate 99, and may be patterned to form a mask pattern 101.

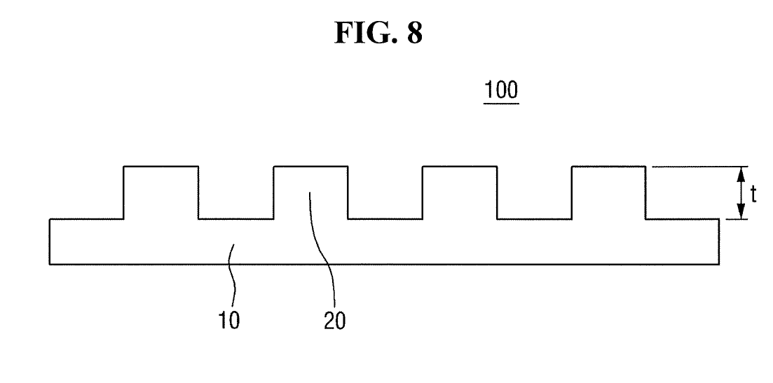

Then, referring to FIGS. 5 and 8, the light transmissive plate 99 may be etched (operation S200). That is, some areas of the light transmissive plate 99 exposed by the mask pattern 101 (see FIG. 7) may be etched by a predetermined thickness t, e.g., portions of the light transmissive plate 99 exposed by the mask pattern 101 may be removed. In this case, the etched thickness t may be adjusted by controlling an etching time. That is, etching time may be adjusted to control the etched thickness t, e.g., etching may be performed for a short period of time in order to decrease the etched thickness t or for a long period of time in order to increase the etched thickness t.

When the light transmissive plate 99 (see FIG. 7) is formed of, e.g., silicon nitride (Si₃N₄), etching may be more easily performed. This is because an etching depth formed depending on the etching time is relatively constant in case of silicon nitride (Si₃N₄).

When the etching process is complete, as shown in FIG. 2, it may be possible to form the zoneplate 100 including the first pattern 10 having the first thickness T1, and the second pattern 20 formed adjacent to the first pattern 10 and having the second thickness T2 larger than the first thickness T1. As described previously, the first and second patterns 10 and 20 of the zoneplate 100 may be formed integrally as a single unit from a same light transmissive plate. For example, the first and second patterns 10 and 20 may be arranged alternately to directly contact each other, e.g., the first and second patterns 10 and 20 may have elliptical shapes with gradually increasing radiuses arranged alternately and concentrically.

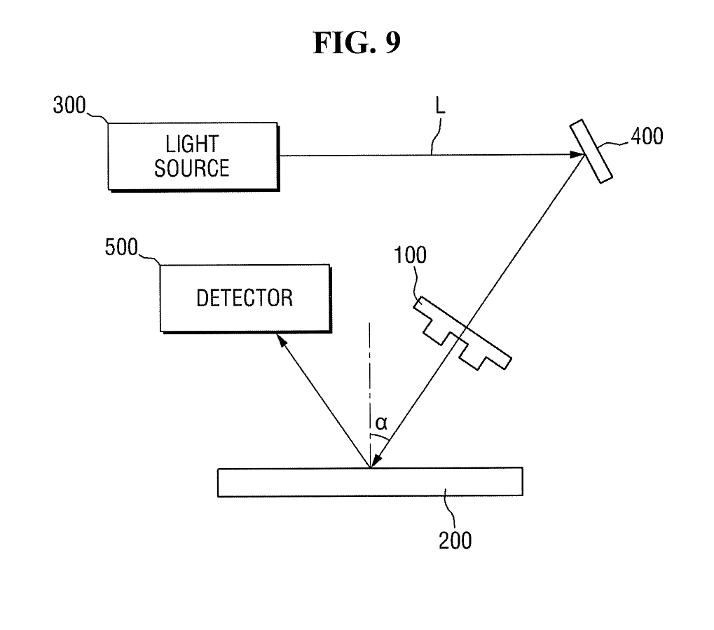

Next, a mask pattern measuring device in accordance with an embodiment will be described with reference to FIG. 9. FIG. 9 is a conceptual block diagram of a mask pattern measuring device in accordance with an embodiment.

Referring to FIG. 9, the mask pattern measuring device may include a light source 300, a mirror 400, the zoneplate 100, the mask 200, and a detector 500. The mirror 400 may be an X-ray mirror 400.

The light source 300 may generate and irradiate light L. In this embodiment, the light L generated from the light source 300 may include extreme ultraviolet (EUV) light, e.g., the light source 300 may generate and irradiate coherent EUV light having a wavelength of about 12 nm to about 14 nm.

The EUV light generated by the light source 300 may be emitted toward the X-ray mirror 400, and may subsequently be reflected from the X-ray mirror 400 toward the zoneplate 100. For example, the X-ray mirror 400 of this embodiment may be configured to reflect only EUV light having a wavelength of about 12 nm to about 14 nm.

The X-ray mirror 400 may be formed of a material such as Pd/C and Mo/Si. For example, the X-ray mirror 400 may have a Mo/Si multilayer structure in which about eighty molybdenum layers and silicon layers are alternately stacked. The molybdenum layers and silicon layers may be thin films formed by sputtering.

The X-ray mirror 400 may be designed such that the EUV light generated by the light source 300 may be incident on a partial region of the mask 200 at a same angle as an incident angle of an exposure device with respect to a normal to the mask 200. In this case, the incident angle α may range from about 4 degrees to about 8 degrees, e.g., may be about 6 degrees.

The reflected EUV light may pass through the zoneplate 100 and may be focused on a partial region of the mask 200. In this case, the zoneplate 100 may exhibit improved light focusing efficiency as described above with reference to FIGS. 1-4.

A mask pattern (not shown) may be formed in the partial region of the mask 200, and the mask pattern may reflect the incident EUV light toward the detector 500. The mask 200 may include a reflective material, e.g., an upper surface of the mask 200 may include a microcircuit pattern of about 45 nm or less.

Meanwhile, although not shown in detail, a moving unit (not shown) may be provided below the mask 200. The moving unit (not shown) may move the mask 200 in an x-axis or y-axis direction, such that the detector 500 may scan the entire upper surface of the mask 200. The detector 500 having received and detected the light reflected from the mask 200 may detect energy of the EUV light and transmit energy information to a computation unit (not shown), thereby measuring the mask pattern (not shown) formed on the mask 200.

Since the mask pattern measuring device in accordance with this embodiment includes the zoneplate 100 with improved light focusing efficiency as described above, measurement efficiency of the entire device may be improved.

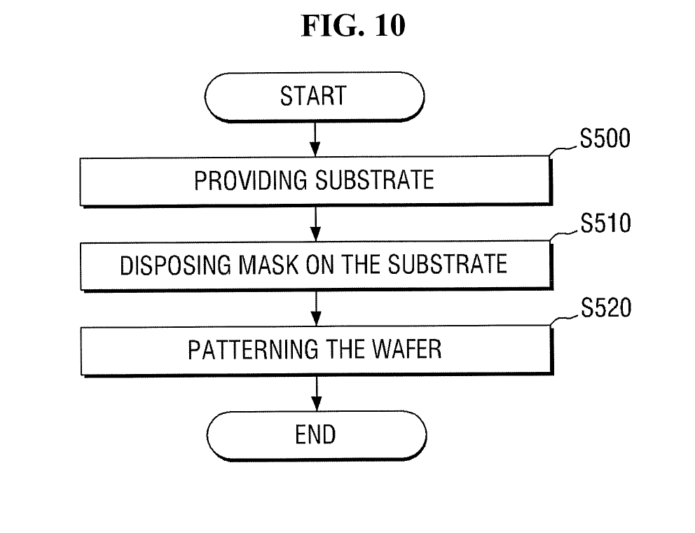

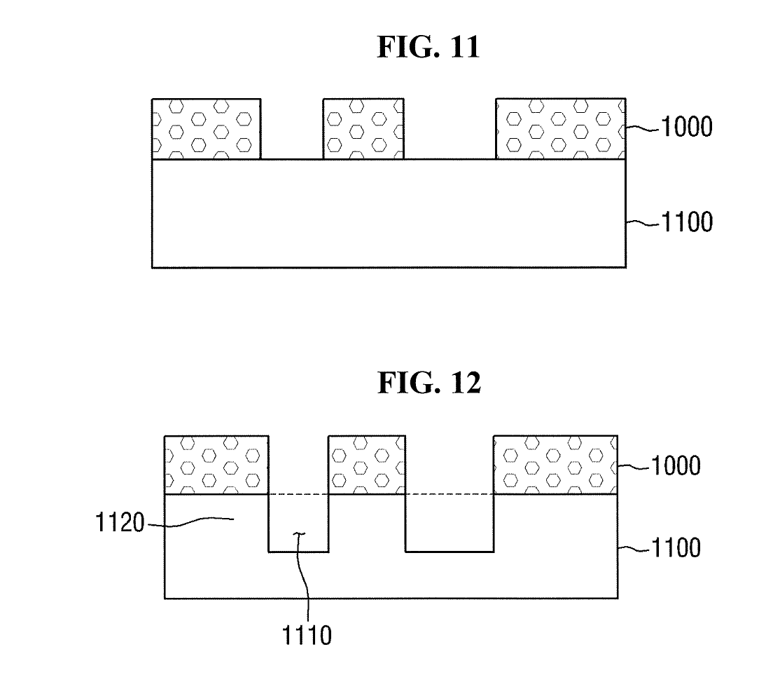

Next, a method for forming a pattern in accordance with an embodiment will be described with reference to FIGS. 10 to 12. FIG. 10 is a flowchart for explaining a method for forming a pattern in accordance with an embodiment, and FIGS. 11 and 12 illustrate intermediate steps for explaining the method for forming a pattern in accordance with the embodiment.

Referring to FIGS. 10 and 11, a substrate 1100 is provided (operation S500). In this case, the substrate 1100 may be, e.g., a semiconductor wafer. Then, referring to FIGS. 10 and 11, a mask 1000 may be disposed on the substrate 1100 (operation S510). In this case, the mask 1000 may be a mask having a mask pattern that has been inspected by using the zoneplate 100 in accordance with the embodiment. In some embodiments, the mask 1000 may be, e.g., a photomask, but example embodiments are not limited thereto.

Then, referring to FIGS. 10 and 12, the substrate 1100 may be patterned using the mask 1000 (operation S520). That is, some areas of the substrate 1100 may be etched using the mask 1000 disposed on the substrate 1100, thereby forming trenches 1110 in the substrate 1100 to define a pattern 1120 in the substrate 1100.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the example embodiments as set forth in the following claims.

What is claimed is:

1. A zoneplate, comprising:
a first pattern having a first thickness, the first pattern including a first material; and
a second pattern adjacent to the first pattern and having a second thickness larger than the first thickness, the second pattern including a second material,
wherein incident light incident on the first pattern from the outside passes through the first pattern, and incident light incident on the second pattern from the outside passes through the second pattern.

2. The zoneplate as claimed in claim 1, wherein the first material and the second material include a same light transmissive material.

3. The zoneplate as claimed in claim 2, wherein a refractive index of the light transmissive material is defined by a+bi, where a and b are real numbers and b is smaller than 0.02.

4. The zoneplate as claimed in claim 3, wherein when the light transmissive material includes silicon nitride (Si₃N₄).

5. The zoneplate as claimed in claim 2, wherein a refractive index of the light transmissive material is n, a wavelength of the incident light is λ, and a difference t between the first thickness and the second thickness is presented by t=(2k−1)π*(n−1)/λ, where k is a natural number.

6. The zoneplate as claimed in claim 5, wherein k is 1.

7. The zoneplate as claimed in claim 1, wherein the first and second pattern are arranged to have constructive interference between non-diffraction light (0th order diffraction light) of first transmission light having passed through the first pattern and 1st order diffraction light of second transmission light having passed through the second pattern.

8. The zoneplate as claimed in claim 7, wherein there is a phase difference of (2k−1) it (k is a natural number) between the first transmission light immediately after passing through the first pattern and the second transmission light immediately after passing through the second pattern.

9. The zoneplate as claimed in claim 8, wherein k is 1.

10. The zoneplate as claimed in claim 1, wherein the first pattern and the second pattern are elliptically shaped and are concentric.

11. A mask pattern measuring device, comprising:
a light source configured to irradiate light;
a zoneplate configured to transmit the light irradiated from the light source, the zoneplate including a first pattern having a first thickness and a second pattern adjacent to the first pattern and having a second thickness larger than the first thickness, the first and second patterns being arranged such that light having passed through the first pattern and light having passed through the second pattern constructively interfere;
a mask having a mask pattern and configured to reflect light transmitted through the zoneplate; and
a detector configured to detect the light reflected from the mask.

12. The mask pattern measuring device as claimed in claim 11, wherein the zoneplate is elliptical, and when an incident angle of incident light incident on the mask is α, a first axis radius of the first pattern is r1, a first axis radius of the second pattern is r2, a second axis radius of the first pattern is r1/(cos α), and a second axis radius of the second pattern is r2/(cos α).

13. The mask pattern measuring device as claimed in claim 11, wherein there is a phase difference of it between the light having passed through the first pattern and light having passed through the second pattern.

14. The mask pattern measuring device as claimed in claim 11, wherein the light source is configured to emit extreme ultraviolet (EUV) light.

15. The mask pattern measuring device as claimed in claim 11, wherein a refractive index of a material included in the first pattern and the second pattern is a+bi, where a and b are real numbers and b is smaller than 0.02.

16. A zoneplate, comprising:
a first pattern having a first thickness; and
a second pattern having a second thickness larger than the first thickness, the second pattern being adjacent the first pattern,
wherein light is incident on and transmitted through the first and second patterns from the outside.

17. The zoneplate as claimed in claim 16, wherein the first and second patterns include a same light transmissive material and are integral with each other.

18. The zoneplate as claimed in claim 16, wherein the first and second pattern are arranged such that light passing through the first pattern and light passing through the second pattern constructively interfere.

19. The zoneplate as claimed in claim 16, wherein the first and second patterns are arranged alternately and in direct contact with each other.

20. The zoneplate as claimed in claim 19, wherein the first and second patterns are concentric.
